(19) United States
(12) Patent Application Publication
(10) Pub. No.: US 2026/0322369 A1
(43) Pub. Date: Oct. 15, 2026

(54) OUTPUT CIRCUIT

(71) Applicant: Socionext Inc., Kanagawa (JP)

(72) Inventor: Masahiro GION, Yokohama-shi (JP)

(21) Appl. No.: 19/695,449

(22) Filed: Jun. 2, 2026

Related U.S. Application Data
(63) Continuation of application No. PCT/JP2023/044496, filed on Dec. 12, 2023.

(51) Int. Cl. H03K 17/042; H03K 5/06; H03K 19/00

(52) U.S. Cl. CPC H03K 17/04206; H03K 5/06; H03K 19/0013; H03K 2217/0027

(57) ABSTRACT

A first transistor has a source connected to VDD1 and a drain connected to an output terminal via a second transistor. A pre-driver receives a signal changing with a data input signal, and gives a gate signal making transitions between VDD1 and the potential of a power supply end to the gate of the first transistor. A drive assist circuit performs an assist operation of temporarily lowering the potential of an output node from VDD2 when an assist signal makes a first transition corresponding to a transition of the gate signal from High to Low, or when the assist signal makes a second transition corresponding to a transition of the gate signal from Low to High.

### CROSS-REFERENCE TO RELATED APPLICATIONS

This is a continuation of International Application No. PCT/JP2023/044496 filed on Dec. 12, 2023. The entire disclosure of this application is incorporated by reference herein.

### BACKGROUND

The present disclosure relates to an output circuit that outputs a signal outside a semiconductor device (large scale integration (LSI)).

With the miniaturization of transistors, the transistor-tolerable voltage stress (withstanding voltage) is increasingly decreasing. To address this, there is known an output circuit that uses transistors low in withstanding voltage and outputs a high-voltage signal.

For example, U.S. Pat. No. 10,355,685 discloses a technique in which an output circuit is provided with a drive assist circuit that performs an assist operation of temporarily decreasing the potential of an output node when a transition corresponding to a transition of a gate signal from High level to Low level is made.

The output circuit of the cited patent document works only at a transition corresponding to a High to Low level transition of the gate signal, i.e., at a transition of rise of a data output signal. However, in these days when lower voltages are being required along with high-speed operation of circuits and reduction in power consumption, desired is an output circuit provided with a control working at transitions of both rise and fall of a signal.

An objective of the present disclosure is providing an output circuit that performs assist operations at transitions of both rise and fall of a signal.

### SUMMARY

According to a mode of the disclosure, an output circuit configured to receive a data input signal and output an output signal changing with the data input signal includes: an output terminal outputting the output signal; a p-type first transistor having a source connected to a first power supply supplying a first potential and a drain connected to a first node; a p-type second transistor having a source connected to the first node and a drain connected to the output terminal; a level shift circuit connected to the first power supply and to a power supply end supplied with a potential lower than the first potential, receiving the data input signal or a signal changing with the data input signal, and outputting a signal making transitions between the first potential and the potential of the power supply end in response to the data input signal; a pre-driver connected to the first power supply and to the power supply end, receiving the signal output from the level shift circuit, and giving a transition signal to a gate of the first transistor as a gate signal, the transition signal making transitions between the first potential and the potential of the power supply end in response to the received signal; and a drive assist circuit connected to a second power supply supplying a second potential lower than the first potential and to a third power supply supplying a third potential lower than the second potential, and supplying the second potential from its output node to the power supply end, wherein the drive assist circuit receives the data input signal or the signal changing with the data input signal as an assist signal, and performs an assist operation of temporarily lowering the potential of the output node from the second potential when the assist signal makes a first transition corresponding to a transition of the gate signal from High level to Low level, or when the assist signal makes a second transition corresponding to a transition of the gate signal from Low level to high level.

According to the above mode, in the output circuit, the first transistor has a source connected to the first power supply supplying a first potential and a drain connected to the output terminal. The level shift circuit and the pre-driver are connected to the first power supply and to a power supply end supplied with a potential lower than the first potential, and supply a transition signal that makes transitions between the first potential and the potential of the power supply end in response to the data input signal to the first transistor as a gate signal. The drive assist circuit supplies a second potential to the power supply end from its output node. Also, the drive assist circuit receives the data input signal or a signal changing with the data input signal as an assist signal. The drive assist circuit performs an assist operation of temporarily lowering the potential of the output node from the second potential when the assist signal makes a first transition corresponding to a transition of the gate signal from High level to Low level, or when the assist signal makes a second transition corresponding to a transition of the gate signal from Low level to High level.

Having the above configuration, when the gate signal makes a transition from High level to Low level, the gate-source voltage of the first transistor can be temporarily increased by the assist operation of the drive assist circuit. Since this can improve the drive capability of the first transistor, the transition of the output signal from Low level to High level can be sped up. Moreover, when the assist signal makes the second transition corresponding to the transition of the gate signal from Low level to High level, the drive assist circuit performs the assist operation of temporarily lowering the potential of the output node from the second potential. Since this increases the operating speed of the pre-driver, the transition of the output signal from High level to Low level can be sped up.

According to the present disclosure, an output circuit that performs assist operations at transitions of both rise and fall of a signal can be implemented.

### BRIEF DESCRIPTION OF THE DRAWINGS

FIG. 1 is a circuit configuration diagram of an output circuit according to the first embodiment.

FIG. 2 is a circuit configuration diagram of a level shift circuit.

FIG. 3 is a waveform chart showing the operation of the output circuit of FIG. 1.

FIG. 4 is a circuit configuration diagram of an output circuit according to the second embodiment.

FIG. 5 is a waveform chart showing the operation of the output circuit of FIG. 4.

FIG. 6 is a circuit configuration diagram of an output circuit according to the third embodiment.

FIG. 7 is a waveform chart showing the operation of the output circuit of FIG. 6.

FIG. 8 is a circuit configuration diagram of an output circuit according to an alteration of the first embodiment.

### DETAILED DESCRIPTION

Embodiments of the present disclosure will be described hereinafter with reference to the drawings described above.

Note that the circuit configuration diagrams referred to hereinafter are simplified illustrations focusing on components related to the present disclosure. Therefore, it should be understood that, in some cases, components illustrated as being connected directly are actually connected indirectly with another component placed between them.

In the following description, nodes and terminals of a circuit and signals passing through such nodes and terminals may be described under the same reference characters, and a power supply and a power supply voltage (potential) of the power supply may be described under the same reference character. Also, the voltages of nodes and terminals may be described as “(terminal or node name)=(character indicating voltage).” Specifically, for example, when the voltage of an output node nc is VDD1 (voltage of a power supply VDD1), it may be described as nc=VDD1.

### First Embodiment

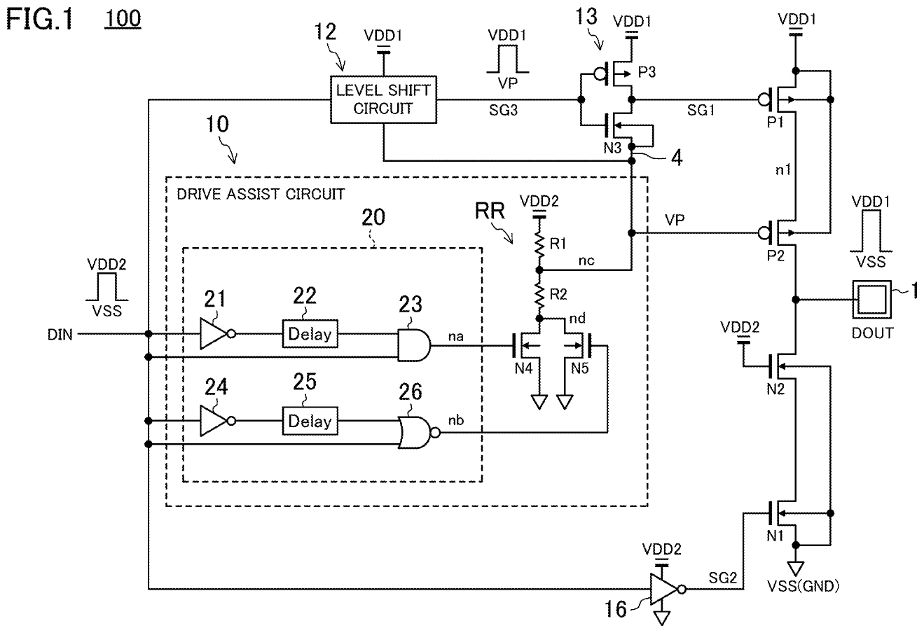

FIG. 1 is a circuit configuration diagram of an output circuit according to the first embodiment. The output circuit 100 of FIG. 1 receives a data input signal DIN and outputs an output signal DOUT that changes with the data input signal DIN. The output signal DOUT is output from an output terminal 1. This output circuit 100 is provided in a signal output part of an LSI, for example. In this case, an output pad of the LSI corresponds to the output terminal 1.

The output circuit 100 is connected to a first power supply VDD1 and to a second power supply VDD2. The potential of the first power supply VDD1 is higher than the potential of the second power supply VDD2. The data input signal DIN makes transitions between a ground potential VSS and the second potential VDD2. The output signal DOUT makes transitions between the ground potential VSS and the first potential VDD1.

The output circuit 100 includes a level shift circuit 12, inverters 13 and 16, p-type transistors P1 and P2, and n-type transistors N1 and N2. In the present disclosure, the transistors are assumed to be metal oxide semiconductor field effect transistors (MOSFETs).

The level shift circuit 12 converts the data input signal DIN to a signal that makes transitions between a potential VP of a power supply end 4 and the first potential VDD1, and supplies the converted signal to the inverter 13.

The inverter 13 is made of a p-type transistor P3 and an n-type transistor N3 of which the gates, and the drains, are mutually connected, and is connected to the first power supply VDD1 and to the power supply end 4 supplied with the potential VP lower than the first potential VDD1. The inverter 13 inverts a signal SG3 received from the level shift circuit 12 and gives the inverted signal to the gate of the p-type transistor P1 as a gate signal SG1. The gate signal SG1 is a signal that makes transitions between the first potential VDD1 and the potential VP of the power supply end 4. The inverter 13 is an example of pre-driver. Note that in the normal state, the second potential VDD2 is supplied as the potential VP.

The p-type transistor P1 (corresponding to the first transistor) has a source connected to the first power supply VDD1 and a drain connected to the output terminal 1 via the p-type transistor P2. That is, the p-type transistor P1 is cascade-connected to the output terminal 1. More specifically, the p-type transistor P1 is connected to the first power supply VDD1 at its source and to a first node n1 at its drain, and the p-type transistor P2 (corresponding to the second transistor) is connected to the first node n1 at its source and to the output terminal 1 at its drain.

The p-type transistor P1 shifts from the nonconductive state to the conductive state when the gate signal SG1 makes a transition from High level (VDD1) to Low level (VP). With this, the potential of the output signal DOUT is raised toward the first potential VDD1, and then the output signal DOUT makes a transition to High level (VDD1).

The inverter 16 inverts the data input signal DIN and gives the inverted signal to the gate of the n-type transistor N1 as a gate signal SG2. The n-type transistor N1 has a source grounded and a drain connected to the output terminal 1 via the n-type transistor N2. The n-type transistor N1 shifts from the nonconductive state to the conductive state when the gate signal SG2 makes a transition from Low level (VSS) to High level (VDD2). With this, the potential of the output signal DOUT is lowered toward the ground potential VSS, and then the output signal DOUT makes a transition to Low level (VSS).

The output circuit 100 further includes a drive assist circuit 10. The drive assist circuit 10 is connected to the second power supply VDD2, and supplies the potential VP from an output node nc. The output node nc is connected to the power supply end 4 and also connected to the gate of the p-type transistor P2. When the drive assist circuit 10 does not perform an assist operation to be described later, it outputs the second potential VDD2 from the output node nc as the potential VP. In this case, since the second potential VDD2 is supplied from the drive assist circuit 10 to the power supply end 4, the gate signal SG1 output from the inverter 13 is a signal that makes transitions between the first potential VDD1 and the second potential VDD2. When the data input signal DIN (corresponding to the assist signal) makes a transition from Low level to High level, the drive assist circuit 10 performs the assist operation of temporarily lowering the potential VP of the output node nc from the second potential VDD2. Note here that the transition of the data input signal DIN from Low level to High level corresponds to the transition of the gate signal SG1 output from the inverter 13 from High level to Low level.

The drive assist circuit 10 includes n-type transistors N4 and N5 of which the sources are connected to the ground VSS, a resistor row RR, and a pulse generation circuit 20. The drain of the n-type transistor N4 and the drain of the n-type transistor N5 are mutually connected at a connection node nd.

The resistor row RR is made of serially-connected resistor parts R1 and R2, and is provided between the second power supply VDD2 and the connection node nd. The connection node between the resistor parts R1 and R2 serves as the output node nc of the drive assist circuit 10.

The pulse generation circuit 20 includes: inverters 21 and 24 receiving the data input signal DIN; a delay circuit 22 receiving the output signal of the inverter 21; a delay circuit 25 receiving the output signal of the inverter 24; an AND gate 23; and a NOR gate 26.

The AND gate 23 receives the data input signal DIN and the output of the delay circuit 22 and gives its output na to the gate of the n-type transistor N4. The output na is in High level for a predetermined time after the transition of the data input signal DIN from Low level to High level. In this way, the inverter 21, the delay circuit 22, and the AND gate 23 implement a circuit that outputs a pulse having a predetermined pulse width when the data input signal DIN makes a transition from Low level to High level.

When the output na is in LOW level, the n-type transistor N4 is in the nonconductive state. At this time, the potential VP of the output node nc is the second potential VDD2. On the contrary, when the output na is in High level, the n-type transistor N4 is in the conductive state. At this time, the potential VP of the output node nc is a potential (called the potential Va here) obtained by dividing the second potential VDD2 by the resistance ratio of the resistor part R1 to R2. The n-type transistor N4 is an example of switching element that becomes conductive when a pulse is output from the output na of the pulse generation circuit 20 and nonconductive when no pulse is output from the output na of the pulse generation circuit 20.

The NOR gate 26 receives the data input signal DIN and the output of the delay circuit 25 and gives its output nb to the gate of the n-type transistor N5. The output nb is in High level for a predetermined time after the transition of the data input signal DIN from High level to Low level. In this way, the inverter 24, the delay circuit 25, and the NOR gate 26 implement a circuit that outputs a pulse having a predetermined pulse width when the data input signal DIN makes a transition from High level to Low level.

When the output nb is in LOW level, the n-type transistor N5 is in the nonconductive state. At this time, the potential VP of the output node nc is the second potential VDD2. On the contrary, when the output nb is in HIGH level, the n-type transistor N5 is in the conductive state. At this time, the potential VP of the output node nc is the potential Va obtained by dividing the second potential VDD2 by the resistance ratio of the resistor part R1 to R2. The n-type transistor N5 is an example of switching element that becomes conductive when a pulse is output from the output nb of the pulse generation circuit 20 and nonconductive when no pulse is output from the output nb of the pulse generation circuit 20.

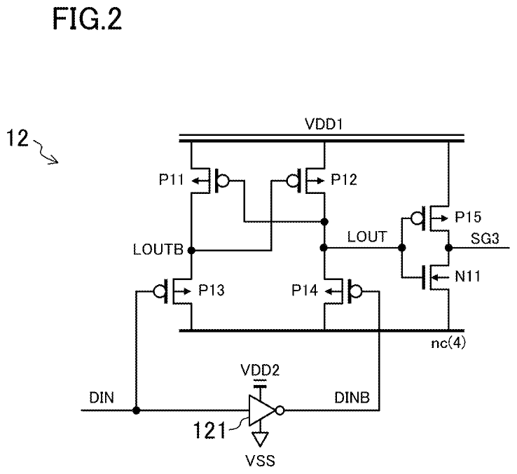

FIG. 2 is a circuit configuration diagram of the level shift circuit 12. Note that the configuration of the level shift circuit 12 is not limited to that of FIG. 2.

The level shift circuit 12 of FIG. 2 receives the data input signal DIN and outputs the signal SG3 that changes with the data input signal DIN.

The level shift circuit 12 is connected to the first power supply VDD1 and to the power supply end 4. The potential of the first power supply VDD1 is higher than the potential of the power supply end 4. As already described, the data input signal DIN makes transitions between the ground potential VSS and the second potential VDD2, and the signal SG3 makes transitions between the potential VP of the power supply end 4 and the first potential VDD1.

The level shift circuit 12 includes p-type transistors P11 to P15, an n-type transistor N11, and an inverter 121.

The inverter 121 receives the data input signal DIN at its input and outputs an inverted input signal DINB.

The p-type transistor P11 is provided between the first power supply VDD1 and a node LOUTB and has a gate connected to a node LOUT. The p-type transistor P13 is provided between the node LOUTB and the power supply end 4 and receives the data input signal DIN at its gate. That is, the p-type transistor P11 and the p-type transistor P13 are provided in series between the first power supply VDD1 and the power supply end 4.

The p-type transistor P12 is provided between the first power supply VDD1 and the node LOUT and has a gate connected to the node LOUTB. The p-type transistor P14 is provided between the node LOUT and the power supply end 4 and receives the inverted input signal DINB at its gate. That is, the p-type transistor P12 and the p-type transistor P14 are provided in series between the first power supply VDD1 and the power supply end 4.

The p-type transistor P15 and the n-type transistor N11 are provided in series between the first power supply VDD1 and the power supply end 4, and their gates, and their drains, are mutually connected, to constitute an inverter for wave-shaping. The wave-shaping inverter receives the signal of the node LOUT, inverts the signal, and outputs the inverted signal as the signal SG3.

### Operation of Output Circuit

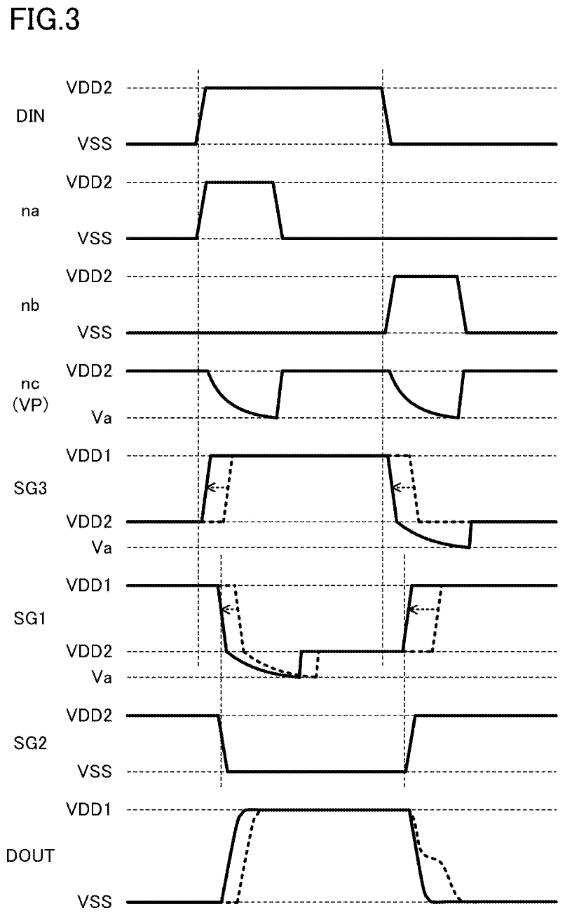

The operation of the circuit shown in FIGS. 1 and 2 will be described using the waveform chart of FIG. 3. Note that, in FIG. 3, for ease of understanding, the change of only the potential VP of the output node nc is emphatically illustrated about three times as large as those of the other signals and potentials. Also, in FIG. 3, the solid lines are waveforms showing the operation of the circuit of this embodiment, and the broken lines are waveforms showing an operation example of the circuit in the cited patent document.

When the data input signal DIN is in Low level, the gate signal SG1 output from the inverter 13 is in High level (VDD1), and so the p-type transistor P1 is in the nonconductive state. On the other hand, the gate signal SG2 output from the inverter 16 is in High level (VDD2), and so the n-type transistor N1 is in the conductive state. As a result, the output signal DOUT is in Low level (VSS).

Also, in the drive assist circuit 10, the output na and the output nb are in LOW level (VSS), and so the n-type transistors N4 and N5 are in the nonconductive state. Therefore, the potential VP of the output node nc is kept in the second potential VDD2.

### Case 1

When the data input signal DIN makes a transition from Low level to High level, the gate signal SG1 output from the inverter 13 makes a transition from High level to Low level, and so the p-type transistor P1 starts to raise the potential of the output signal DOUT. At this time, however, in the drive assist circuit 10, the output na becomes High level for a predetermined time. Since the n-type transistor N4 becomes the conductive state when the output na is in High level, the potential VP of the output node nc falls from the second potential VDD2 toward the potential Va. Since this lowers the potential of the power supply end 4 from the second potential VDD2, the potential of the gate signal SG1 output from the inverter 13 further falls from the second potential VDD2. Once the output na resumes Low level, the n-type transistor N4 becomes the nonconductive state. Therefore, the potential VP of the output node nc resumes the second potential VDD2, and the potential of the gate signal SG1 also resumes the second potential VDD2. At this time, the output nb remains Low level, and so the n-type transistor N5 remains OFF.

In the level shift circuit 12, when the data input signal DIN makes a transition from Low level to High level, the inverted input signal DINB makes a transition from High level to Low level, and so the p-type transistor P14 turns ON. Since this causes a transition of the potential of the node LOUT to the voltage Va of the power supply end 4, the gate-source voltage Vgs of the p-type transistor P15 can be made sufficiently large, raising the drive capability of the p-type transistor P15. With this, the transition of the signal SG3 from Low level to High level is hastened.

As described above, when the data input signal DIN makes a transition from Low level to High level, the potential of the gate signal SG1 given to the p-type transistor P1 is further lowered, for a predetermined time, from the second potential VDD2 supplied from an external power supply. This can temporarily increase the gate-source voltage of the p-type transistor P1, and thus improve the drive capability of the p-type transistor P1 for the output signal DOUT. In the level shift circuit 12, also, as described above, the gate-source voltage Vgs of the p-type transistor P15 can be sufficiently increased, and thus the drive capability of the p-type transistor 15 can be improved. In this way, the transition of the output signal DOUT from Low level to High level can be sped up (see the solid lines in FIG. 3).

### Case 2

Next, when the data input signal DIN makes a transition from High level to Low level, the gate signal SG2 output from the inverter 16 makes a transition from Low level to High level, and so the n-type transistor N1 starts to lower the potential of the output signal DOUT. Also, the p-type transistor P1 starts a transition from the conductive state to the nonconductive state. At this time, in the drive assist circuit 10, the output nb becomes High level for a predetermined time. Since the n-type transistor N5 becomes the conductive state when the output nb is in High level, the potential VP of the output node nc falls from the second potential VDD2 toward the potential Va. Since this lowers the potential of the power supply end 4 from the second potential VDD2, the potential of the gate signal SG3 output from the level shift circuit 12 to the inverter 13 further falls from the second potential VDD2. Once the output nb resumes Low level, the n-type transistor N5 becomes the nonconductive state. Therefore, the potential VP of the output node nc resumes the second potential VDD2, and the potential of the gate signal SG3 also resumes the second potential VDD2. At this time, the output na remains Low level, and so the n-type transistor N4 remains OFF.

In the level shift circuit 12, when the data input signal DIN makes a transition from High level to Low level, the p-type transistor P13 turns ON. Since this causes a transition of the potential of the node LOUTB to the voltage Va of the power supply end 4, the gate-source voltage Vgs of the p-type transistor P12 can be made sufficiently large, raising the drive capability of the p-type transistor P12. With this, the transition of the node LOUT from Low level to High level and the transition of the signal SG3 from High level to Low level are hastened.

As described above, when the data input signal DIN makes a transition from High level to low level, the potential of the gate signal SG3 received by the inverter 13 is further lowered, for a predetermined time, from the second potential VDD2 supplied from an external power supply. This can temporarily increase the gate-source voltage of the p-type transistor P3 of the inverter 13, and thus improve the drive capability of the p-type transistor P3. In the level shift circuit 12, also, as described above, the gate-source voltage Vgs of the p-type transistor P12 can be sufficiently increased, and thus the drive capability of the p-type transistor 12 can be improved. That is, the operating speeds of the level shift circuit 12 and the inverter 13 are improved. In this way, the transition of the output signal DOUT from High level to Low level can be sped up (see the solid lines in FIG. 3).

Moreover, the configuration of FIG. 1 can respond to variations in the first potential VDD1 and the second potential VDD2 supplied from external power supplies. That is, if the first potential VDD1 falls or the second potential VDD2 rises, the gate-source voltage of the p-type transistor P1 will decrease, degrading the drive capability. In this embodiment, however, the gate-source voltage Vgs of the p-type transistor P1 can be sufficiently increased for a predetermined time after the transition of the gate signal SG1 from High level to Low level. Similarly, the gate-source voltage Vgs of the p-type transistor P3 of the inverter 13 can be sufficiently increased for a predetermined time after the transition of the gate signal SG1 from Low level to High level, that is, after the transition of the gate signal SG3 from High level to Low level.

### Effects of First Embodiment

According to this embodiment, in the output circuit 100, when the data input signal DIN makes a first transition corresponding to the transition of the gate signal SG1 from High level to Low level, the drive assist circuit 10 performs the assist operation of temporarily lowering the potential VP of the output node nc from the second potential VDD2. Therefore, when the gate signal SG1 makes a transition from High level to Low level, turning the p-type transistor P1 to the conductive state to drive the output signal DOUT, the gate-source voltage of the p-type transistor P1 can be temporarily increased by the assist operation of the drive assist circuit 10. Since this can improve the drive capability of the p-type transistor P1, the transition of the output signal DOUT from Low level to High level can be sped up. In this way, high-speed operation of the output circuit 100 can be achieved without the necessity of increasing the size of the p-type transistor P1.

Also, when the data input signal DIN makes a second transition corresponding to the transition of the gate signal SG1 from Low level to High level, the drive assist circuit 10 performs the assist operation of temporarily lowering the potential VP of the output node nc from the second potential VDD2. Since this can increase the operating speed of the inverter 13, the transition of the output signal DOUT from Low level to High level can be sped up. In this way, high-speed operation of the output circuit 100 can be achieved without the necessity of increasing the size of the p-type transistor P1.

Moreover, in this embodiment, a signal making transitions between the first potential VDD1 and the potential VP of the power supply end 4 in response to the data input signal DIN is supplied to the inverter 13. With this, the operating speed of the level shift circuit 12 improves both when the data input signal DIN performs the first transition and when it performs the second transition, and thus high-speed operation of the output circuit 100 can be achieved.

While the resistor row RR is made of two resistor parts R1 and R2 in the configuration of FIG. 1, the configuration is not limited to this. For example, the resistor row RR may be made of a plurality of serially-connected resistor parts, and any of connection nodes between the resistor parts may be used as the output node nc. Alternatively, the resistor parts constituting the resistor row RR may be formed by combining a plurality of resistive elements, or may be formed using transistor resistances.

Also, the level shift circuit 12 receives the first potential VDD1 and the potential VP supplied to the power supply end 4 in the configuration of FIG. 1. Alternatively, the level shift circuit 12 may be configured to receive the second potential VDD2 in place of the potential VP supplied to the power supply end 4.

### Second Embodiment

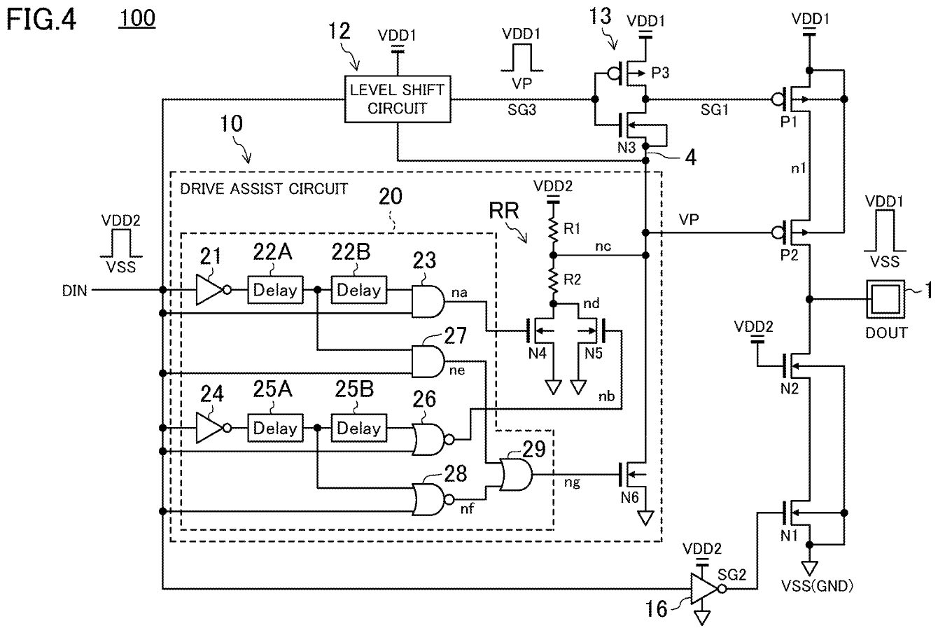

FIG. 4 is a circuit configuration diagram of an output circuit according to the second embodiment. In FIG. 4, components corresponding to those in FIG. 1 are denoted by the same reference characters. The following description will be made centering on differences from the first embodiment. Note that blocks and elements (e.g., transistors and resistors) denoted by the same reference characters in FIGS. 1 and 4 are not intended to be the same in configurations and various design parameters, process parameters, and the like. That is, configurations in which elements denoted by the same reference characters in FIGS. 1 and 4 have parameters different from each other also fall within the technical scope of the present disclosure. This also applies to the relationships between other drawings.

The output circuit 100 of FIG. 4 is different from the output circuit 100 of FIG. 1 in the internal configuration of the drive assist circuit 10.

In FIG. 4, the drive assist circuit 10 includes n-type transistors N4, N5, and N6 connected to the ground VSS at their sources, a resistor row RR, and a pulse generation circuit 20. The drain of the n-type transistor N4 and the drain of the n-type transistor N5 are mutually connected at a connection node nd.

The resistor row RR, made of serially-connected resistor parts R1 and R2, is provided between the second power supply VDD2 and the connection node nd. The connection node between the resistor parts R1 and R2 serves as an output node nc of the drive assist circuit 10.

The pulse generation circuit 20 includes: inverters 21 and 24 receiving the data input signal DIN; 2-stage (serially-connected) delay circuits 22A and 22B receiving the output signal of the inverter 21; 2-stage (serially-connected) delay circuits 25A and 25B receiving the output signal of the inverter 24; AND gates 23 and 27; NOR gates 26 and 28; and an OR gate 29.

The AND gate 23 receives the data input signal DIN and the output of the second-stage delay circuit 22B and gives its output na to the gate of the n-type transistor N4. The output na is in High level for a predetermined time after the transition of the data input signal DIN from Low level to High level. In this way, the inverter 21, the delay circuits 22A and 22B, and the AND gate 23 implement a pulse generation circuit that outputs a pulse having a predetermined pulse width when the data input signal DIN makes a transition from Low level to High level. As in the first embodiment, the n-type transistor N4 is an example of switching element that becomes conductive when a pulse is output from the output na of the pulse generation circuit 20 and nonconductive when no pulse is output from the output na of the pulse generation circuit 20.

The NOR gate 26 receives the data input signal DIN and the output of the second-stage delay circuit 25B and gives its output nb to the gate of the n-type transistor N5. The output nb is in High level for a predetermined time after the transition of the data input signal DIN from High level to Low level. In this way, the inverter 24, the delay circuits 25A and 25B, and the NOR gate 26 implement a circuit that outputs a pulse having a predetermined pulse width when the data input signal DIN makes a transition from High level to Low level. As in the first embodiment, the n-type transistor N5 is an example of switching element that becomes conductive when a pulse is output from the output nb of the pulse generation circuit 20 and nonconductive when no pulse is output from the output nb of the pulse generation circuit 20.

The n-type transistor N6 is provided between the output node nc and the ground VSS. The AND gate 27 receives the data input signal DIN and the output of the first-stage delay circuit 22A and gives its output ne to an input of the OR gate 29. The NOR gate 28 receives the data input signal DIN and the output of the first-stage delay circuit 25A and gives its output nf to an input of the OR gate 29. The OR gate 29 receives the output ne and the output nf and gives its output ng to the gate of the n-type transistor N6.

That is, the inverter 21, the delay circuit 22A, and the AND gate 27 constitute a circuit that outputs a second pulse to the node output ne when the data input signal DIN makes a transition from Low level to High level. Also, the inverter 24, the delay circuit 25A, and the NOR gate 28 constitute a circuit that outputs a second pulse to the output nf when the data input signal DIN makes a transition from High level to Low level. In other words, the inverters 21 and 24, the delay circuits 22A and 25A, the AND gate 27, and the NOR gate 28 constitute a second pulse generation circuit that outputs a second pulse when the data input signal DIN makes a transition from Low level to High level or when the data input signal DIN makes a transition from High level to Low level. The width of the second pulse output from the second pulse generation circuit is smaller than the width of the pulse output from the pulse generation circuit constituted by the inverters 21 and 24, the delay circuits 22A, 22B, 25A, and 25B, the AND gate 23, and the NOR gate 26.

The signal subjected to the logical OR of the output ne and the output nf by the OR gate 29 is given to the gate of the n-type transistor N6. Therefore, the n-type transistor N6 is an example of second switching element that becomes conductive when a second pulse is output from the second pulse generation circuit and nonconductive when no second pulse is output from the second pulse generation circuit.

In this embodiment, the drive assist circuit 10 performs the lowering of the potential VP of the output node nc by way of two routes, i.e., the route via the n-type transistors N4 and N5 and the route via the n-type transistor N6.

### Operation of Output Circuit

### Case 1

First, the operation when the data input signal DIN makes a transition from Low level to High level will be described.

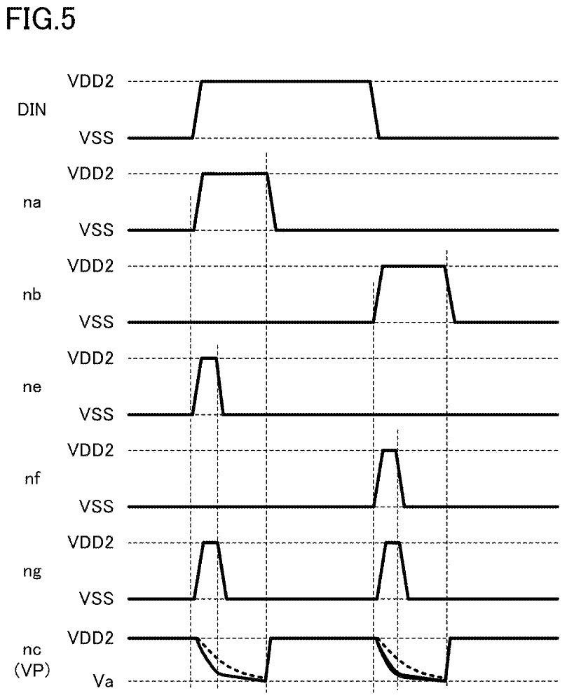

As shown in the waveform chart of FIG. 5, the output na of the pulse generation circuit 20 is in High level for a predetermined time after the transition of the data input signal DIN from Low level to High level. Also, the output ne is in High level for a time shorter than the time for the output na after the transition of the data input signal DIN from Low level to High level. Therefore, at the beginning of the transition of the data input signal DIN from Low level to High level, since both the outputs na and ne are in High level, both the n-type transistors N4 and N6 become conductive. As a result, the potential VP of the output node nc is lowered at high speed. Thereafter, with the output ne becoming Low level, the n-type transistor N6 becomes nonconductive, so that the lowering of the potential VP of the output node nc is performed by only the n-type transistor N4. The potential VP then becomes the potential Va obtained by dividing the second potential VDD2 by the resistance ratio of the resistor part R1 to R2.

### Case 2

Next, the operation when the data input signal DIN makes a transition from High level to Low level will be described.

As shown in the waveform chart of FIG. 5, the output nb of the pulse generation circuit 20 is in High level for a predetermined time after the transition of the data input signal DIN from High level to Low level. Also, the output nf is in High level for a time shorter than the time for the output nb after the transition of the data input signal DIN from High level to Low level. Therefore, at the beginning of the transition of the data input signal DIN from High level to Low level, since both the outputs nb and nf are in High level, both the n-type transistors N5 and N6 become conductive. As a result, the potential VP of the output node nc is lowered at high speed. Thereafter, with the output nf becoming Low level, the n-type transistor N6 becomes nonconductive, so that the lowering of the potential VP of the output node nc is performed by only the n-type transistor N5. The potential VP then becomes the potential Va obtained by dividing the second potential VDD2 by the resistance ratio of the resistor part R1 to R2.

### Effects of Second Embodiment

According to this embodiment, as in the first embodiment, when the data input signal DIN makes a first transition corresponding to the transition of the gate signal SG1 from High level to Low level, the potential of the gate signal SG1 received by the p-type transistor P1 is further lowered from the second potential VDD2 supplied from an external power supply. With this, the gate-source voltage of the p-type transistor P1 can be temporarily increased and thus the drive capability of the p-type transistor P1 for the output signal DOUT can be improved. Therefore, the transition of the output signal DOUT from Low level to High level can be sped up.

Moreover, in this embodiment, since the falling of the output node nc at the beginning of the first transition is hastened, the gate-source voltage and drive capability of the p-type transistor P1 can be increased fast, and this can achieve speedup of the circuit. Also, since the n-type transistor N6 becomes nonconductive on the way, making the transition mild, it is possible to curb an occurrence of ringing noise caused by a sharp voltage change.

Also, when the data input signal DIN makes a second transition corresponding to the transition of the gate signal SG1 from Low level to High level, the drive assist circuit 10 performs the assist operation of temporarily lowering the potential VP of the output node nc from the second potential VDD2. Since this increases the operating speed of the inverter 13, the transition of the output signal DOUT from High level to Low level can be sped up.

Moreover, in this embodiment, since the falling of the output node nc at the beginning of the first transition is hastened, the gate-source voltage and drive capability of the p-type transistor P3 of the inverter 13 can be increased fast, and this can achieve speedup of the output circuit 100. Also, since the n-type transistor N6 becomes nonconductive on the way, making the transition mild, it is possible to curb an occurrence of ringing noise caused by a sharp voltage change.

Furthermore, in this embodiment, the lowering of the potential VP of the output node nc can be performed at high speed and with high precision. In the first embodiment, to achieve high-speed lowering of the potential VP, it is necessary to reduce the resistance of the resistor parts R1 and R2 of the resistor row RR. However, in a semiconductor device, to reduce the resistance, it is necessary to increase the size of the element, and this causes increase in circuit area. In this embodiment, it is possible to lower the potential VP at high speed by way of the n-type transistor N6, and set the final potential Va with high precision by way of the resistor row RR. In this way, since it is acceptable for the resistor parts R1 and R2 of the resistor row RR to have high resistance, increase in circuit area can be curbed.

### Third Embodiment

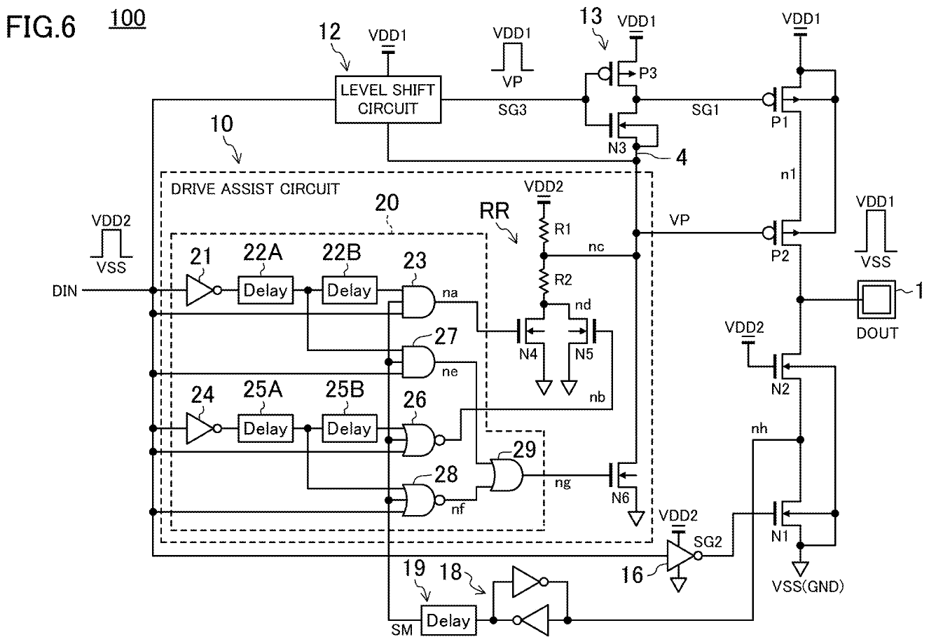

FIG. 6 is a circuit configuration diagram of an output circuit according to the third embodiment. In FIG. 6, components corresponding to those of the output circuit 100 of FIG. 4 are denoted by the same reference characters. The following description will be made centering on differences from the second embodiment.

In comparison with the output circuit 100 of FIG. 4, the output circuit 100 of FIG. 6 includes a configuration of feeding back the change of the output signal DOUT to the drive assist circuit 10. Specifically, the output circuit 100 includes: a latch circuit 18 that receives the potential of a connection node nh between the n-type transistor N1 and the n-type transistor N2; and a delay circuit 19 that receives the output of the latch circuit 18. The signal output from the delay circuit 19 is given, as a monitor signal SM for detecting the change of the output signal DOUT, to 3-input AND gates 23 and 27 and 3-input NOR gates 26 and 28 as their additional inputs. The latch circuit 18 and the delay circuit 19 constitute a monitor circuit that outputs the monitor signal SM changing with the output signal DOUT. Also, in the drive assist circuit 10 of FIG. 6, the AND gates 23 and 27 and the NOR gates 26 and 28 are all 3-input circuits.

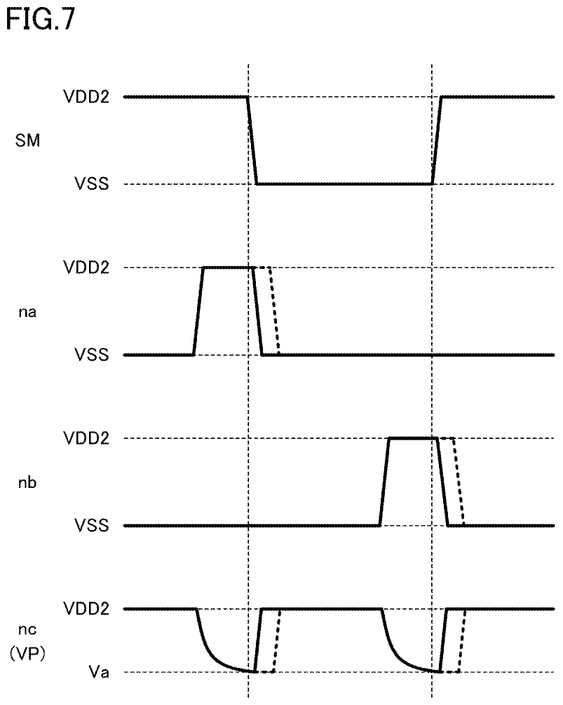

As shown in the waveform chart of FIG. 7, the monitor signal SM makes a transition from High level to Low level when the potential of the connection node nh rises to a predetermined level at the transition of the output signal DOUT from Low level to High level. The timing of this transition is however adjusted by the delay circuit 19. This change of the monitor signal SM indicates that the output signal DOUT has made a transition from Low level to High level. As described in the second embodiment, the potential VP of the output node nc of the drive assist circuit 10 is lowered after the transition of the data input signal DIN from Low level to High level. However, when the monitor signal SM makes a transition from High level to Low level, all of the output na of the AND gate 23, the output nb of the NOR gate 26, the output ne of the AND gate 27, and the output nf of the NOR gate 28 are forced down to Low level, whereby the potential VP of the output node nc resumes the second potential VDD2.

### Effects of the Third Embodiment

According to this embodiment, as in the second embodiment, the transitions of the output signal DOUT from Low level to High level and from High level to Low level can be sped up. Moreover, the lowering of the potential VP of the output node nc can be performed at high speed and with high precision.

Also, in this embodiment, with the feedback of the signal SM to the drive assist circuit 10, the assist operation by the drive assist circuit 10 can be stopped when the output signal DOUT is driven at high speed. This can curb excess current consumption in the drive assist circuit 10.

While the potential of the connection node nh between the n-type transistor N1 and the n-type transistor N2 is monitored for detection of the change of the output signal DOUT in this embodiment, the technique of detecting the change of the output signal DOUT is not limited to this. For example, the output signal DOUT may be monitored directly, or when there is a circuit part receiving the output signal DOUT in the LSI, the change of the output signal DOUT may be monitored from this circuit part.

### Other Embodiment

Note that the technique in the present disclosure is not limited to the configurations described in the above embodiments, but many alterations such as changes, replacements, additions, and omissions can be made appropriately within the technical ideas of the present disclosure by a person having ordinary knowledge in the art. Also, the components described in the above embodiments can be combined to provide a new embodiment.

For example, a configuration of feeding back the change of the output signal DOUT as the one disclosed in the third embodiment may be applied to the configuration of the first embodiment.

### Alteration

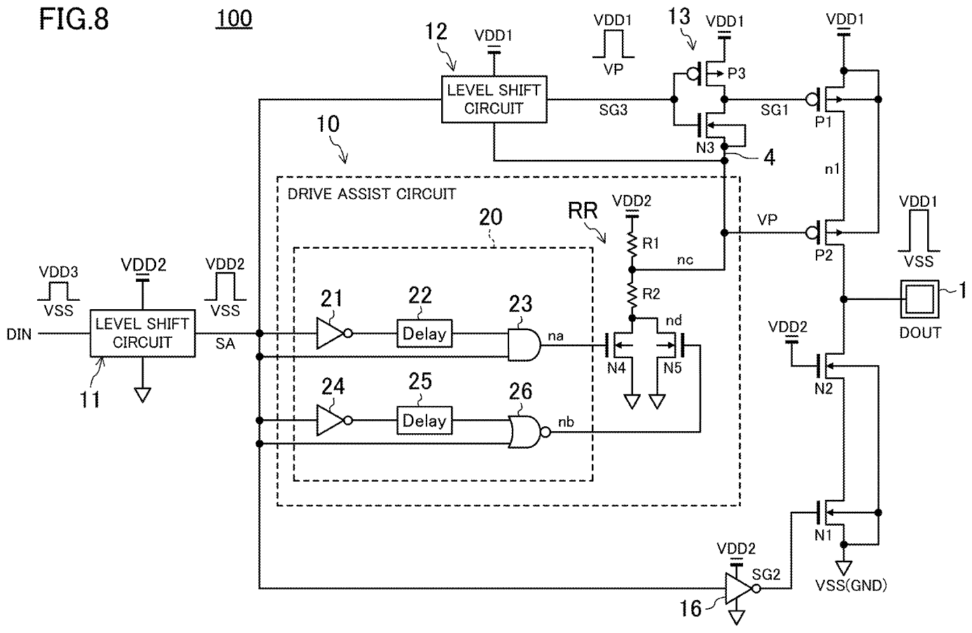

FIG. 8 is a circuit configuration diagram of an output circuit according to an alteration of the first embodiment. In FIG. 8, components corresponding to those in FIG. 1 are denoted by the same reference characters. The following description will be made centering on differences from the first embodiment.

In the first embodiment, the case of the transitions of the data input signal DIN between the ground potential VSS and the second potential VDD2 was described. FIG. 8 shows a configuration example of the output circuit 100 in the case where a data input signal DIN having an amplitude smaller than that between the ground potential VSS and the second potential VDD2 is input. Specifically, in the example of FIG. 8, the input signal DIN makes transitions between the ground potential VSS and a third potential VDD3 (VDD3<VDD2).

The output circuit of FIG. 8 includes a level shift circuit 11 in addition to the configuration of FIG. 1. The level shift circuit 11 receives the data input signal DIN having a small amplitude (making transitions between the ground potential VSS and the third potential VDD3, for example), converts the received signal to a signal SA (corresponding to the assist signal) making transitions between the ground potential VSS and the second potential VDD2, and outputs the signal SA. The signal SA is given to the level shift circuit 12 and the drive assist circuit 10, in place of the data input signal DIN in the first embodiment. The other configuration is the same as that of the first embodiment, and similar effects to those in the first embodiment are obtained.

According to the present disclosure, an output circuit capable of high-speed operation without increase in circuit area can be implemented. The present disclosure is therefore useful for speedup and area reduction of an LSI, for example.

1. An output circuit configured to receive a data input signal and output an output signal changing with the data input signal, comprising:
an output terminal outputting the output signal;
a p-type first transistor having a source connected to a first power supply supplying a first potential and a drain connected to a first node;
a p-type second transistor having a source connected to the first node and a drain connected to the output terminal;
a level shift circuit connected to the first power supply and to a power supply end supplied with a potential lower than the first potential, receiving the data input signal or a signal changing with the data input signal, and outputting a signal making transitions between the first potential and the potential of the power supply end in response to the data input signal;
a pre-driver connected to the first power supply and to the power supply end, receiving the signal output from the level shift circuit, and giving a transition signal to a gate of the first transistor as a gate signal, the transition signal making transitions between the first potential and the potential of the power supply end in response to the received signal; and
a drive assist circuit connected to a second power supply supplying a second potential lower than the first potential and to a third power supply supplying a third potential lower than the second potential, and supplying the second potential from its output node to the power supply end,
wherein
the drive assist circuit receives the data input signal or the signal changing with the data input signal as an assist signal, and performs an assist operation of temporarily lowering the potential of the output node from the second potential when the assist signal makes a first transition corresponding to a transition of the gate signal from High level to Low level, or when the assist signal makes a second transition corresponding to a transition of the gate signal from Low level to High level.

2. The output circuit of claim 1, wherein
the drive assist circuit includes
a pulse generation circuit receiving the assist signal and outputting a pulse having a predetermined pulse width when the assist signal makes the first transition or when the assist signal makes the second transition,
a resistor row made of a plurality of serially-connected resistor parts, one end of the resistor row being connected to the second power supply, and a connection node between the resistor parts serving as the output node, and
a switching element provided between the other end of the resistor row and ground power supply, receiving the output of the pulse generation circuit, and becoming a conductive state when the pulse is output from the pulse generation circuit and a nonconductive state when no pulse is output from the pulse generation circuit.

3. The output circuit of claim 2, wherein
the drive assist circuit further includes
a second pulse generation circuit receiving the assist signal and outputting a second pulse shorter in pulse width than the pulse when the assist signal makes the first transition or when the assist signal makes the second transition, and
a second switching element provided between the output node and the ground power supply, receiving the output of the second pulse generation circuit, and becoming a conductive state when the second pulse is output from the second pulse generation circuit and a nonconductive state when the second pulse is not output from the second pulse generation circuit.

4. The output circuit of claim 1, further comprising a monitor circuit configured to monitor a change of the output signal and output a monitor signal changing with the output signal,
wherein
the drive assist circuit receives the monitor signal, and, after starting the assist operation with the first transition of the assist signal, stops the assist operation when the monitor signal shows a change indicating that the output signal has made a transition from Low level to High level, or, after starting the assist operation with the second transition of the assist signal, stops the assist operation when the monitor signal shows a change indicating that the output signal has made a transition from High level to Low level.
